(19) United States
(12) Patent Application Publication
(10) Pub. No.: US 2006/0097400 A1
(43) Pub. Date: May 11, 2006

(54) Substrate via pad structure providing reliable connectivity in array package devices

(75) Inventors: Mark Gerald M. Cruz, Baguio (PH); Jerry G. Cayabyab, Baguio (PH); Joel T. Medina, Baguio (PH)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/904,289

(22) Filed: Nov. 3, 2004

(51) Int. Cl. H01L 23/48

(52) U.S. Cl. 257/774

(57) ABSTRACT

A substrate via pod structure providing reliable connectivity in array package devices. The reliability is attained by providing a protruding metal stud in the via area, with the stud being connected to a conductive metal trace (which provides conductive path to a bond pad of an integrated circuit). Due to the presence of the metal stud, increased area of contact is obtained between a solder ball and the conductive metal trace. In an embodiment, the stud contains a well surrounded by protruding portions. The slopes of the protruding portions lead to enhanced resistance in different directions to various cohesive forces that would be present during mounting operations, thereby avoiding solder ball cracking problems.

### BACKGROUND OF THE INVENTION

1. Field of the Invention

The present invention relates to manufacturing (or fabrication) technologies of integrated circuits, and more specifically to a fabrication process and a packaging structure which provides reliable connectivity.

2. Related Art

Array packages (e.g., ball grid arrays and chip scale packages) are generally used to package dies with a large number of pads. An array package contains multiple solder balls, with each solder ball providing connectivity from a pad (representing input or output of a circuit) to an external source/device. Each solder ball generally protrudes outside (on the bottom side) of the package and is used to connect each pad to a corresponding terminal of the external device/source.

The connectivity between a pad and a corresponding solder ball is often provided using one or more conductive materials (e.g., metal layers) and a substrate via structure. A substrate via structure generally contains vias through which conductive metal is laid to provide connectivity (across the dielectric substrate) It is generally desirable that the solder ball be in contact with the conductive material, which is coupled to the pad. The contact ensures that there is a conductive path between the pad and the external device/source, as desired.

Losing of contact between a solder ball and the conductive material is some times of concern since the resulting disconnect could render the die and external device/source combination non-operational. There are several activities, due to which, such a disconnect may be caused after packaging of a die.

One such activity which may cause disconnect, is mounting of a die onto a customer board. In one prior approach, adhesive pastes are applied to the intended points of contact (with the solder balls) on the customer board and the solder balls, the solder balls and the customer board are placed with a desired alignment, and heat is applied to the contact points (e.g., by using heated gas) to mount the packaged die onto the customer board. Such operations cause the corresponding terminals on the customer board to be physically attached to the corresponding solder balls, thereby providing a conducting path between the pads and the corresponding terminals.

However, one problem encountered during such a mounting activity is that various forces (cohesive force from the pastes, gravitational pull downwards, any relative movement between the packaged die and grid array) may cause the undesirable disconnect, which is often referred to solder ball cracking. It is generally desirable that such disconnects be prevented at least for an increased yield (i.e., fraction of dies that are in operational condition after mounting divided by the total number of dies fabricated).

In one prior approach described in U.S. Pat. No. 6,596,620 (hereafter 620 patent) entitled, “BGA substrate via structure” issued on Jul. 22, 2003, to Cheng et al., (incorporated in its entirety into the present application) a solid, planar, solder able metal core (conductive material above) extending from a chip side surface through at least about one third of the dielectric substrate thickness is provided while packaging the chip/die. The solder able core improves the height to width ratio (referred to as aspect ratio) of the via, and an improved aspect ratio allows enhance contact of a solder ball with the metal core, and avoids some of the problems noted above.

However, one problem with such a prior approach is that the contact area between the solder able metal core and solder ball may not be sufficient to provide a desired adhesive strength between solder balls and the conductive material. Accordingly what is needed is an improved approach to minimize solder ball cracking in array packages.

### BRIEF DESCRIPTION OF THE DRAWINGS

The present invention will be described with reference to the following accompanying drawings.

FIG. 1 is a three dimensional view of an example ball grid array package when split open and sectioned at the center of holes.

FIG. 2A is a cross section of a pad structure in array packing in one prior embodiment prior to mounting.

FIG. 2B illustrates the solder ball cracking phenomenon in one prior embodiment.

FIG. 3A depicts the manner in which the contact area between a solder ball and a conductive metal trace is enhanced to avoid the solder ball cracking problem in one prior embodiment.

FIG. 4 is a cross section view of a pad via structure in an embodiment of the present invention.

FIG. 5 depicts the bottom view of a stud provided according to an aspect of the present invention.

FIG. 6 depicts the three dimensional view of provided according to an aspect of the present invention.

FIG. 7 depicts the manner in which a solder ball makes contact with the conductive material provided in a pad via substrate provided according to an aspect of the present invention.

FIG. 8 is a flow-chart illustrating the manner in which integrated circuits can be fabricated according to an aspect of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

1. Overview

A pad structure provided according to an aspect of the present invention includes a protruded metal stud (e.g., copper) extending from a conductive metal trace connecting to a bond pad of a die, and a solder ball is soldered around the protruded metal stud. Due to the angular shape of the stud, the contact area between the solder ball and the conductive metal trace is enhanced. The enhanced contact area can lead to a correspondingly more adhesion strength between the solder balls and the conductive metal trace, thereby reducing the solder ball cracking problem.

Various aspects of the present invention are described below with reference to an example problem. Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well-known structures or operations are not shown in detail to avoid obscuring the invention.

2. Example Integrated Circuit

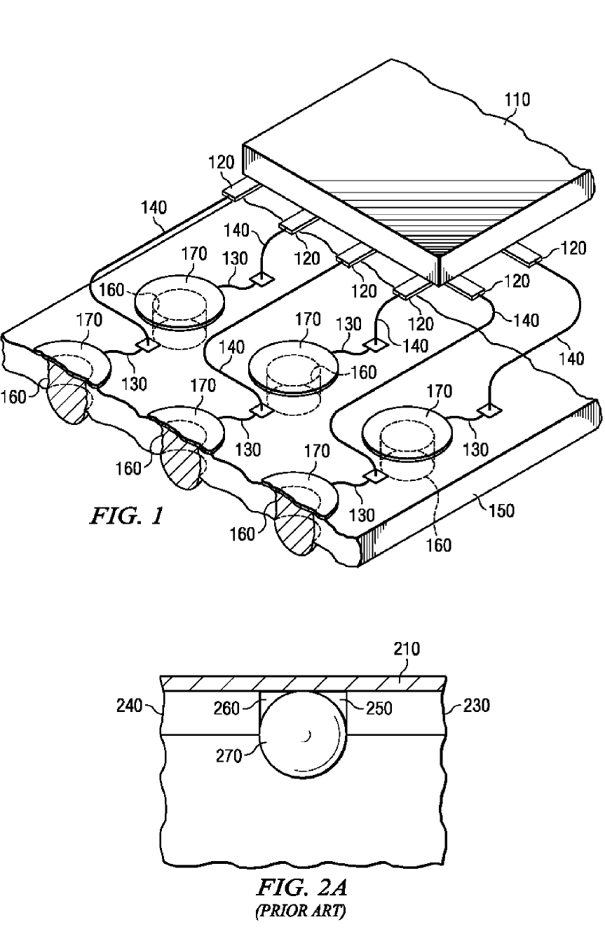

FIG. 1 is a diagram of an integrated circuit (IC) illustrating the details of a array packaging in one embodiment. IC 100 is shown containing die 110, bond pad 120, conductive metal trace 130 (shown with two lines), conductive wire (shown with a single line) 140, dielectric substrate 150, via 160, and solder ball 170 (shown across hatched at the bottom). Each component is described below in further detail.

Bond pad 120 generally represents an input or output path, and is shown provided on die 110. Conductive wire 140 connects bond pad 120 to conductive metal trace 130. Via 160 is shown provided in substrate 150, and solder ball 170 makes contact with metal trace 130 through via 160. The combination of conductive metal trace 130 and via 160 thus provides connectivity between solder ball 170 and bond pad 120, and forms a pad via structure (here after “pad structure”).

Various aspects of the present invention enhance the area of contact between metal trace 130 and solder ball 170, as described in sections below in further detail. The advantages of the present invention may be clearer in comparison to prior embodiments. Accordingly, some example prior embodiments are described below in further detail.

3. Prior Pad Structure

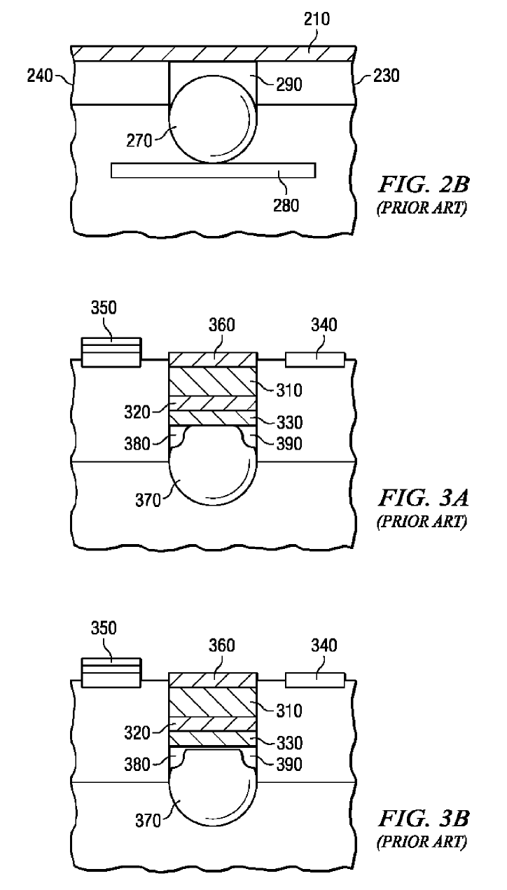

FIG. 2A is a cross section of a pad structure in array packing in one prior embodiment prior to mounting. Solder ball 270 is shown making contact to conductive metal trace 210 in a via shown between substrate portions 230 and 240. During mounting, solder ball 270 may liquify (become liquid), and the resulting liquid may flow into areas 250 and 260, which could strengthen the physical adhesion/bond between solder 270 and conductive metal trace 210 after the pad structure is cooled post-mounting.

FIG. 2B illustrates the solder ball cracking phenomenon when the pad structure of FIG. 2A is heated. PCB 280 (or the various adhesion/cohesive forces in operation during mounting) pulls solder ball 270, causing a disconnect (and thus the solder ball cracking problem) between solder ball 270 and conductive metal trace 210. The disconnect is represented by a gap (area 290) between solder ball 270 and conductive metal trace 210.

An approach of the 620 patent, which addresses the solder ball cracking problem of above, is briefly described below with reference to FIGS. 3A and 3B.

FIG. 3A depicts the manner in which the contact area between a solder ball and a conductive metal trace is enhanced to avoid the solder ball cracking problem. As may be observed, additional layers of metal (e.g., copper core 310, nickel 320, gold 330) are laid/platted in the via portion (between substrate portions 340 and 350) below conductive metal trace 360.

The additional layers reduce the aspect ratio (height to width ratio, width representing the distance between two substrate portions 340 and 350, and height representing the thickness of the substrate portion). The reduced aspect ratio enables the contact area to be increased, thereby reducing the probability of occurrence of the disconnection.

Further, air gaps 380 and 390 might expand during the mounting process (due to the heat applied), thereby causing a downward pressure on solder ball 370. The downward pressure enhances the possibility of disconnection.

Various aspects of the present invention overcome at least some of the problems noted above.

4. Using Studs in Pad Via Structures for Reliable Connectivity

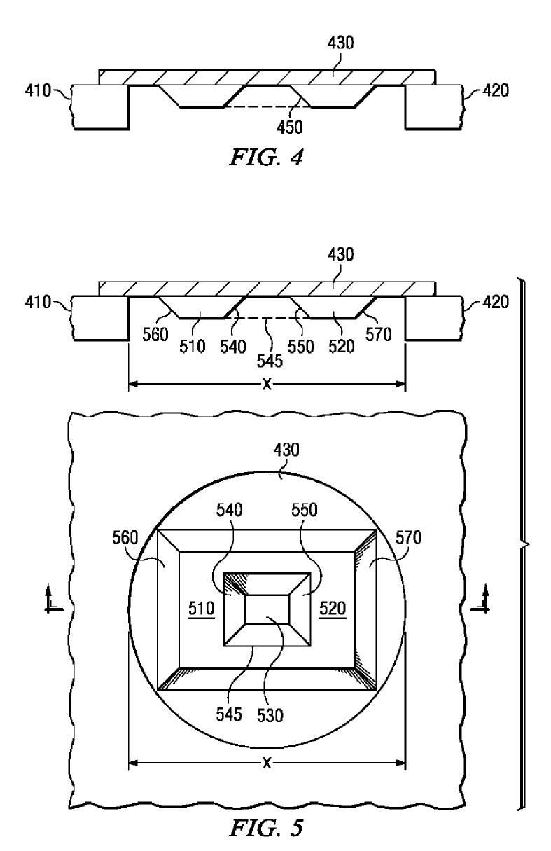

FIG. 4 is a cross section view of a pad via structure in an embodiment of the present invention. The pad via structure is shown containing substrate portions 410 and 420, conductive metal trace 430, and stud 450.

The gap between substrate portions 410 and 420 forms a via. Conductive metal trace 430 may cover the via completely. Stud 450, contained in the via, enhances the reliability of connection due to enhanced contact area and resistance in different directions to various cohesive forces that would be present during mounting operations.

In the embodiment of FIG. 4, stud 450 is implemented as an extension of conductive metal trace 430 formed of copper. Such an approach simplifies the fabrication process by reducing the number of fabrication steps. However, studs can be implemented using other conductive materials. For example, in FIG. 3 above, studs can implemented using copper core 310, nickel 320, gold 330, noted above.

In general, a stud refers to any protruding structure in the via. The protrusion generally provides enhanced contact area. The manner in which such a benefit is achieved will be clearer by examining the structure of an example embodiment of stud 450.

5. Example Stud

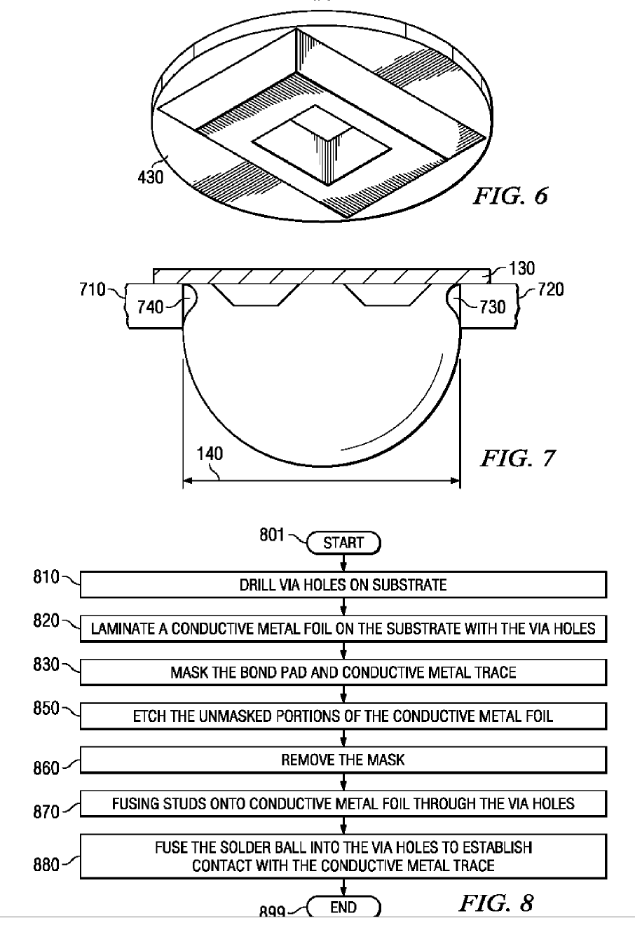

FIG. 5 depicts the bottom view of stud 450 while illustrating the relationship of various portions of the view with the corresponding portions of FIG. 4. FIG. 6 depicts the three dimensional view of stud 450 in the same embodiment.

Continuing with combined reference o FIGS. 5 and 6, portion 530 represents the well, portions 510 and 520 continuous protruding portion of the stud, and portions 540 and 550 represent the inward wedges toward the well portion from the protruding portions. Portions 560 and 570 represent outward wedges sloping toward conductive metal trace 430. The relationship between portion 545 (shown as dotted line in FIG. 4 as well), is demonstrated.

FIG. 7 depicts the manner in which a solder ball makes contact with the conductive material provided in a pad via substrate provided according to an aspect of the present invention. Areas 730 and 740 represent the areas in which air is trapped during the fusion process.

As may be readily appreciated, there is an increased contact area between solder ball 710 and conductive metal trace 430. For illustration, the area of contact in the 620 patent would be proportionate to the width of the via. In contrast, the area of contact would be more than such an amount, as determined by the length of various slopes in the stud. The increased contact area leads to enhanced reliability of connectivity between the solder ball and the conductive metal trace.

In addition, it may be appreciated that slope portions (corresponding to inward wedges 540 and 550, and outward wedges 560 and 570, noted above with respect to FIG. 5) provide resistance in different directions to various cohesive forces that would be present during mounting operations. As a result, the reliability of connectivity is further enhanced.

Also, in comparison with the 620 patent, the total air trapped may be less since the outward slope (provided by the outward wedges of the stud) guide the molten solder ball to the corners. In addition, the pressure due to the trapped air might be distributed doing the slopes (of the outward studs), thereby reducing the pressure on the solder ball. Reliability of connectivity may be further enhanced as a result.

The integrated circuits (ICS) containing such pad via structures can be fabricated by various manufacturing processes using equipment generally available in the market place. An example manufacturing process is described briefly below.

6. Manufacturing Process

FIG. 8 is a flow-chart illustrating the manner in which integrated circuits can be fabricated according to an aspect of the present invention. The description is provided with reference to Figures above, merely for illustration. However, the flow-chart can be used to fabricate other integrated circuits as will be apparent to one skilled in the relevant arts by reading the disclosure provided herein. The flow-chart begins in step 801, in which control immediately passes to step 810.

In step 810, a via holes are drilled on a substrate. In general, substrates are made of dielectric material such as those from polyimide family, from composite polymer, or inorganic substrate material. Via holes can be drilled using any of several known techniques.

In step 820, a conductive metal foil is laminated on a side of the substrate with the via holes. The holes generally need to be of suitable diameter, generally depending on various manufacturing parameters and size constraints. In an embodiment, a copper metal foil is used for the conductive metal foil.

In step 830, the bond pad conductive metal trace are masked. In step 850, the unmasked portions of the conductive metal foil are etched. In general, the etching technique needs to complement the masking technique. Masking may be performed by techniques such as printing with appropriate glass masking, etching may be performed by using a chemical(s) such as Cupric Chloride.

In step 860, the mask is removed to expose the bond pads and conductive metal trace remaining after the etching operation. In step 870, studs are fused to the conductive metal trace through the via holes, by using techniques such a deposition or plating of a conductive material on to the conductive traces through the via holes. In a embodiment, the studs are made of the same material as that of conductive metal trace. However, other conductive materials can also be used instead, as appropriate for the specific situation. Similarly, even though a single stud is shown in the described embodiments, multiple studs may be provided in each via.

In step 880, the solder ball is fused into the via holes to establish contact with the conductive metal trace. In an embodiment, the fusing is attained by first applying solder paste to hold the solder ball in contact with the stud, and then transferring appropriate heat to the solder ball. Thus, the desired integrated circuit with enhanced reliability of connectivity to an external source/device, is obtained. The method ends in step 899.

7. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

What is claimed is:

1. A substrate via pad structure providing a reliable connection to a ball, comprising:
a substrate containing a via hole;
a conductive trace covering said via hole; and
a stud protruding in said via hole and being coupled to said conductive trace,
whereby said ball can be attached in said via hole to said substrate via pad structure and enhanced contact area is provided due to said stud thereby enhancing the reliability of connection of said ball.

2. The substrate via pad of claim 1, wherein said stud comprises a well which is surrounded by a protruding portion.

3. The substrate via pad of claim 2, wherein said stud is also made of the same material as said metal trace.

4. The substrate via pad of claim 3, wherein said conductive metal trace is made of copper.

5. The substrate via pad of claim 1, wherein said stud is implemented as an extension of said conductive trace.

6. A method of fabricating an integrated circuit, said method comprising:
laminating a conductive metal foil on a substrate having a via hole;
masking said metal foil according to a desired pattern of a bond pad and a trace;
etching unmasked portions of said conductive metal foil;
removing the mask after said etching; and
fusing a stud onto conductive metal foil through said via hole.

7. The method of claim 6, further comprising fusing a ball into said via hole to establish contact with said conductive metal trace.

8. The method of claim 6, wherein said stud comprises a well which is surrounded by a protruding portion.

9. The method of claim 8, wherein said stud is also made of the same material as said metal trace.

10. The method of claim 9, wherein said conductive metal trace is made of copper.

11. The method of claim 6, wherein said stud is implemented as an extension of said conductive trace.
